(19) United States
(12) Patent Application Publication
(10) Pub. No.: US 2012/0169709 A1
(43) Pub. Date: Jul. 5, 2012

(54) Gate driving circuit and display device including the same

(76) Inventors: Seung Kyu Lee, Yongin-City (KR); Dong-Hoon Lee, Yongin-City (KR); Joo-Sun Yoon, Yongin-City (KR); Jinwoo Park, Yongin-City (KR); Jinwook Yang, Yongin-City (KR); Sangjin Park, Yongin-City (KR)

(21) Appl. No.: 13/200,397

(22) Filed: Sep. 23, 2011

(30) Foreign Application Priority Data
Dec. 31, 2010 (KR) 10-2010-0139990

(51) Int. Cl. G09G 5/00; H03K 3/00

(52) U.S. Cl. 345/215; 327/109

(57) ABSTRACT

A gate driving circuit includes a pre-charge unit, a pull-up unit, a first capacitor, and a discharge unit. The pre-charge unit pre-charges a first node in response to a first input signal. The pull-up unit outputs a gate driving signal for driving a gate line to a first clock signal in response to a signal at the first node. The first capacitor is connected between the first node and a first voltage. The discharge unit discharges the first node in response to a second input signal and a second clock signal.

### CROSS-REFERENCE TO RELATED APPLICATIONS

This U.S. non-provisional patent application claims priority under 35 U.S.C. §119 of Korean Patent Application No. 10-2010-0139990, filed on Dec. 31, 2010, the entire contents of which are hereby incorporated by reference.

### BACKGROUND

The present disclosure herein relates to a display device.

As a type of user interface, mounting a display device on an electronic system is indispensable. Flat panel display devices are widely being used for the light, thin, short, small, and low power consuming electronic devices. Flat panel displays include Organic Light Emitting Diodes (OLEDs), Liquid Crystal Displays (LCDs), Field Emission Display (FEDs), Vacuum Fluorescent Displays (VFDs), and Plasma Display Panels (PDPs).

Such display devices include a display panel and a driving circuit for driving the display panel. The driving circuit is configured with a gate driving circuit and a data driving circuit.

### SUMMARY

The present disclosure provides a gate driving circuit with enhanced reliability and a display device including the same.

Embodiments provide a gate driving circuit including: a pre-charge unit pre-charging a first node in response to a first input signal; a pull-up unit outputting a gate driving signal for driving a gate line to a first clock signal in response to a signal of the first node; a first capacitor connected between the first node and a first voltage; and a discharge unit discharging the first node in response to a second input signal and a second clock signal.

In some embodiments, the first capacitor may include an active-to-metal capacitor, wherein an active terminal is connected to the first node and a metal terminal is connected to the first voltage.

In other embodiments, the first voltage may be set to have a voltage level between a ground voltage and a first operation voltage when the active terminal of the active-to-metal capacitor has an n type, and the first voltage may be set to have a voltage level between the ground voltage and a second operation voltage when the active terminal of the active-to-metal capacitor has a p type.

In still other embodiments, the pre-charge unit may include: a first transistor connected between a second voltage and a second node, and having a gate controlled by a first input signal; and a second transistor connected between the second voltage and the first node, and having a gate controlled by the first input signal.

In even other embodiments, the pull-up unit may include a third transistor connected between the first clock signal and the gate line, and having a gate connected to the first node.

In yet other embodiments, the gate driving circuit may further include a fourth transistor connected between the gate line and the second node, and having a gate controlled by a signal of the gate line.

In further embodiments, the discharge unit may include: a fifth transistor connected between the second node and a third voltage, and having a gate controlled by a second input signal; a sixth transistor connected between the second node and the second operation voltage, and having a gate connected to a third node; a seventh transistor connected between the second node and the first node, and having a gate connected to the third node; an eighth transistor connected between the second node and the first node, and having a gate controlled by the second input signal; a second capacitor connected between the first clock signal and the third node; a ninth transistor connected between the third node and the second operation voltage, and having a gate connected to the first node; a tenth transistor connected between the gate line and the second operation voltage, and having a gate connected to the third node; and an eleventh transistor connected between the gate line and the second operation voltage, and having a gate connected the second clock signal.

In still further embodiments, the pre-charge unit may include: a first transistor connected between the first input signal and a fourth node, and having a gate connected to a second voltage; a second transistor connected between the second input signal and the fourth node, and having a gate connected to a third voltage; and third and fourth transistors sequentially connected between the fourth node and the first node in series, and respectively having gates connected to the second clock signal.

In even further embodiments, the pull-up unit may include fifth and sixth transistors sequentially connected between the first clock signal and the gate line in series, and respectively having gates connected to the first node.

In yet further embodiments, the discharge unit may include: seventh and eighth transistors sequentially connected between the third voltage and a fifth node in series, and respectively having gates connected to the first input signal; ninth and tenth transistors sequentially connected between the second voltage and the fifth node in series, and respectively having gates connected to the second input signal; eleventh and twelfth transistors sequentially connected between the first node and the second operation voltage in series, and respectively having gates connected to the fifth node; a twelfth transistor connected between the second operation voltage and the fifth node, and having a gate connected to a control signal; a second capacitor connected between the fifth node and the second operation voltage; and a fourteenth transistor connected between the gate line and the second operation voltage, and having a gate connected to the fifth node.

In other embodiments, a display device includes: a display panel including a plurality of gate lines, a plurality of source lines perpendicularly intersecting the gate lines, and a plurality of pixels which are respectively formed at intersection points of the gate lines and source lines; a first gate driving circuit driving gate lines of a group among the plurality of gate lines, and including a plurality of first stages which are dependently connected thereto; and a second gate driving circuit driving gate lines of another group among the plurality of gate lines, and including a plurality of second stages which are dependently connected thereto, wherein each of the first and second stages includes: a pre-charge unit pre-charging a first node in response to a first input signal; a pull-up unit outputting a gate driving signal for driving a gate line to a first clock signal in response to a signal of the first node; a first capacitor connected between the first node and a first voltage; and a discharge unit discharging the first node in response to a second input signal and a second clock signal.

In some embodiments, the first gate driving circuit may drive odd-numbered gate lines, and the second gate driving circuit may drive even-numbered gate lines.

In other embodiments, the first capacitor may include an active-to-metal capacitor, wherein an active terminal is connected to the first node and a metal terminal is connected to the first voltage.

In still other embodiments, the first voltage may be set to have a voltage level between a ground voltage and a first operation voltage when the active terminal of the active-to-metal capacitor has an n type, and the first voltage may be set to have a voltage level between the ground voltage and a second operation voltage when the active terminal of the active-to-metal capacitor has a p type.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a block diagram illustrating a configuration of a Liquid Crystal Display (LCD) device according to an embodiment;

FIG. 2 is a diagram illustrating a detailed configuration of gate driver of FIG. 1;

FIG. 3 is a circuit diagram illustrating a detailed configuration of an ith stage in the gate driver of FIG. 2;

FIG. 4 is a diagram illustrating a detailed configuration of a gate driver according to another embodiment;

FIG. 5 is a timing diagram of signals used in the gate driver of FIG. 4;

FIG. 6 is a circuit diagram illustrating a detailed configuration of an ith stage in the gate driver of FIG. 4; and

FIG. 7 is a timing diagram of signals used in an ith stage of FIG. 6.

### DETAILED DESCRIPTION

Exemplary embodiments will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

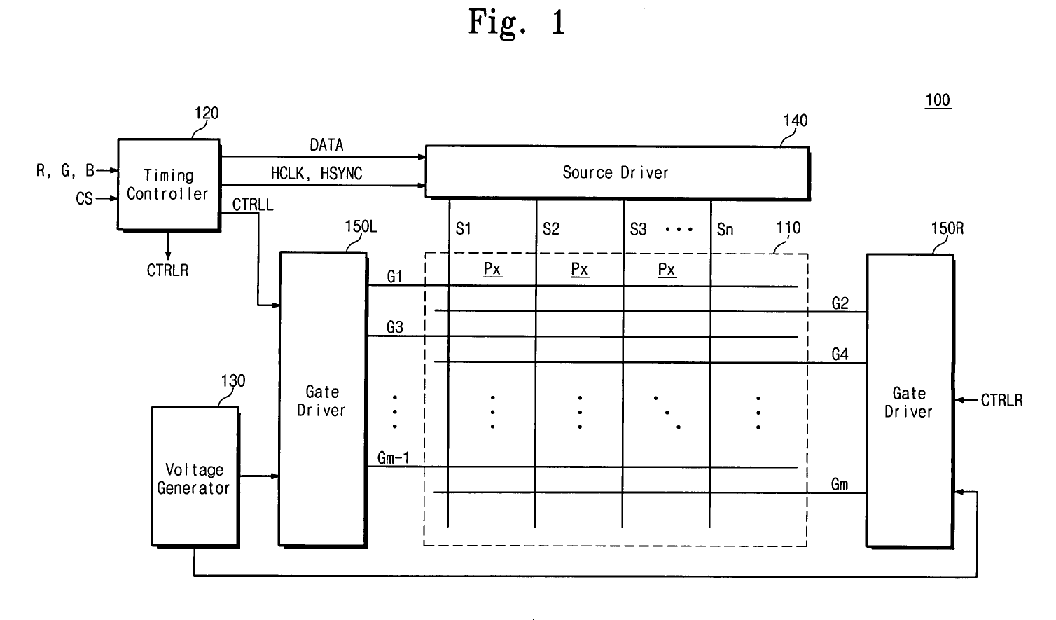

FIG. 1 is a block diagram illustrating a configuration of a Liquid Crystal Display (LCD) device according to an embodiment.

Referring to FIG. 1, an LCD device 100 according to an embodiment includes a liquid crystal panel 110, a timing controller 120, a voltage generator 130, a source driver 140, and gate drivers 150L and 150R.

The liquid crystal panel 110 includes a plurality of gate lines, a plurality of source lines perpendicularly intersecting the gate lines, and a plurality of pixels Px that are respectively formed at intersection points of the gate lines and source lines. The pixels are arranged in a matrix type. Each of the pixels includes a thin film transistor that has a gate electrode connected to a gate line and a source electrode connected to a source line, a liquid crystal capacitor, and a storage capacitor. One end of the liquid crystal capacitor is connected to a drain electrode of the thin film transistor and one end of the storage capacitor is connected to the drain electrode of the thin film transistor. In such a pixel structure, the gate lines are sequentially selected by the gate drivers 150L and 150R, and when a pulse type of gate-on voltage is applied to the selected gate line, a thin film transistor of a pixel connected to the gate line is turned on, and then the source driver 140 applies a voltage including pixel information to each of the source lines. The voltage is applied to a liquid crystal capacitor and a storage capacitor through a thin film transistor of a corresponding pixel to drive the capacitors, and thus a certain display operation is performed.

The timing controller 120 receives video data signals RGB and control signals CS from an external graphic source. The timing controller 120 outputs a horizontal sync signal HSYNC and a horizontal clock signal HCLK necessary for driving of the source driver 140 and outputs control signals CTRLL and CTRLR necessary for driving of the gate drivers 150L and 150R, on the basis of the received control signals CS.

The source driver 140 receives an image data signal DATA, the horizontal sync signal HSYNC and the horizontal clock signal HCLK from the timing controller 120 to generate source driving signals S1 to Sm for driving the source lines of the liquid crystal panel 110.

The voltage generator 130 generates voltages necessary for driving of the gate drivers 150L and 150R. The voltage generator 130 may further generate voltages necessary for driving of the gate drivers 150L and 150R and various voltages necessary for the operation of the display device 100.

The gate driver 150L outputs gate line driving signals G1, G3, . . . , Gm−1 for sequentially driving odd-numbered gate lines according to the control signals CTRLL provided from the timing controller 120. The gate driver 150L outputs gate line driving signals G2, G4, . . . , Gm for sequentially driving even-numbered gate lines according to the control signals CTRLR provided from the timing controller 120. The gate lines of the liquid crystal panel 110 are sequentially scanned by the gate drivers 150L and 150R. Herein, scanning denotes that pixels connected to a gate line receiving the gate-on voltage are putted in a state where data may be written, by sequentially applying the gate-on voltage to the gate lines.

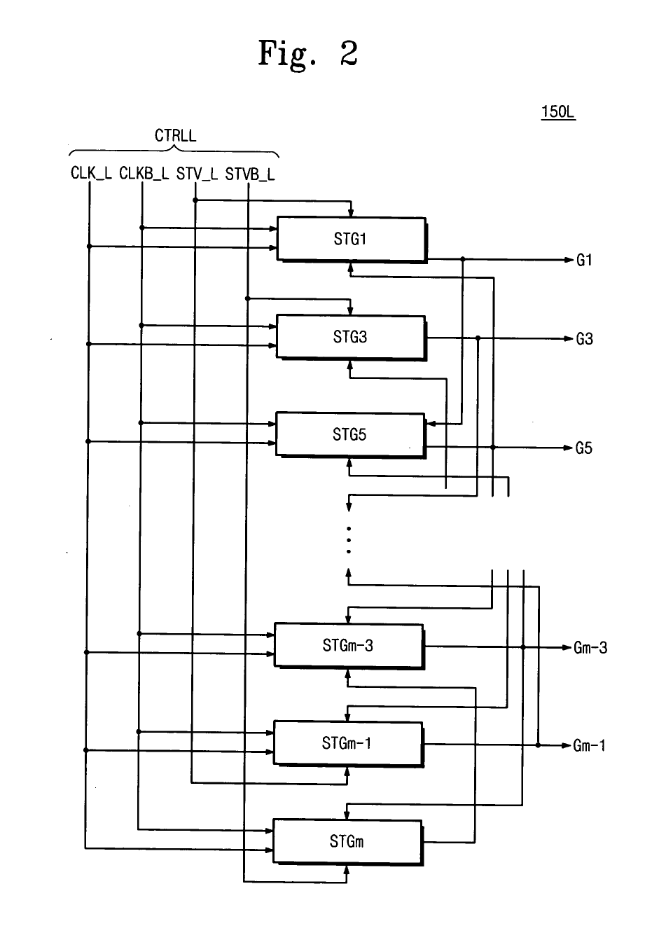

FIG. 2 is a diagram illustrating a detailed configuration of the gate driver of FIG. 1.

Referring to FIG. 2, the gate driver 150L includes a plurality of stages STG1 to STGm−1. The stages STG1 to STGm−1 are connected in a cascade structure, and the stages STG1 to STGm−1, other than a final stage STGm, are connected to the odd-numbered gate lines in one-to-one correspondence relationship. Each of stages STG1 to STGm receives the control signals CTRLL, i.e., first and second clock signals CLK_L and CLKB_L and vertical start signals STV_L and STVB_L from the timing controller 120 of FIG. 1. Although not shown, each of the stages STG1 to STGm receives first to third voltages V1, DIR and DIRB and a second operation voltage VGL from the voltage generator 130.

The stages STG1 and STGm−1 receive the vertical start signal STV_L from the timing controller 120, and the stages STG3 and STGm receive the vertical start signal STVB_L from the timing controller 120. Otherwise, the ith (k≠) stage STGi receives the output of the i−4th stage STGi−4, i.e., the gate line driving signal Gi−4 as a first input signal, and receives the output of the i+4th stage STGi+4, i.e., the gate line driving signal Gi+4 as a second input signal. The stages STG1 to STGm−1 output the gate line driving signals G1 to Gm−1, respectively.

Similarly to the gate driver 150L of FIG. 2, the gate driver 150R of FIG. 1 includes a plurality of stages STG2 to STGm+1. Similarly to the stages STG1 to STGm of the gate driver 150L, the stages STG2 to STGm+1 are connected in a cascade structure.

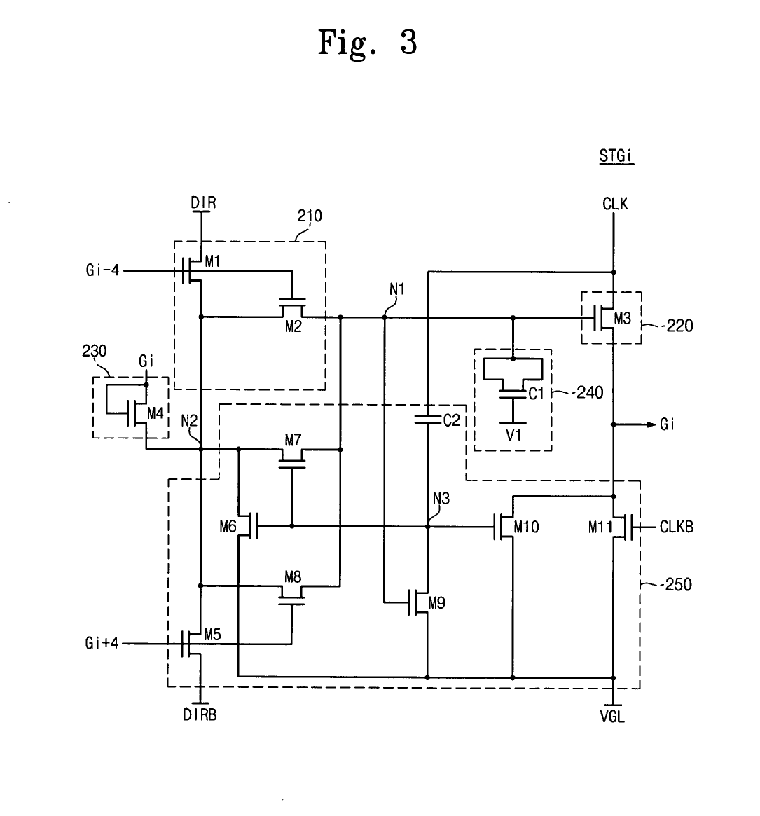

FIG. 3 is a circuit diagram illustrating a detailed configuration of the ith stage in the gate driver of FIG. 2. In the specification, the detailed configuration of the ith stage STGi is illustrated and described, but the stages STG1 to STGm+1 of the gate drivers 150L and 150R have the same configurations as those of the ith stage STGi and operate similarly to the ith stage STGi. Therefore, clock signals CLK_L and CLK_R are indicated as a first clock signal CLK without discrimination, and clock signals CLKB_L and CLKB_R are indicated as a second clock signal CLKB without discrimination.

Referring to FIG. 3, the stage STGi includes a pre-charge unit 210, a pull-up unit 220, a holding unit 230, a boosting unit 240, and a discharge unit 250. The pre-charge unit 210 includes first and second transistors M1 and M2. The first transistor M1 is connected between a second voltage DIR and a second node N2, and has a gate controlled by a first input signal Gi−4. The second transistor M2 is connected between the second node N2 and a first node N1, and has a gate connected to the first input signal Gi−4.

The pull-up unit 220 includes a third transistor M3. The third transistor M3 is connected between the first clock signal CLK and a gate line to which the gate line driving signal Gi is output, and has a gate connected to the first node N1.

The holding unit 230 includes a fourth transistor M4. The fourth transistor M4 is connected between the gate line driving signal Gi and the second node N2, and has a gate controlled by the gate line driving signal Gi.

The boosting unit 240 includes a first capacitor C1. The first capacitor C1 is configured as an active-to-metal capacitor. An active terminal of the first capacitor C1 is connected to the first node N1, and a metal terminal of the first capacitor C1 is connected to a first voltage V1.

For example, if the first capacitor C1 is implemented as an NMOS transistor having an n-type active terminal, the first voltage V1 has a voltage level between a ground voltage and a first operation voltage VGH. If the first capacitor C1 is implemented as a PMOS transistor having a p-type active terminal, the first voltage V1 has a voltage level between the ground voltage and a second operation voltage VGL.

The discharge unit 250 includes fifth to eleventh transistors M5 to M11, and a second capacitor C2. The fifth transistor M5 is connected between the second node N2 and the third voltage DIRB, and has a gate controlled by a second input signal Gi+4. The sixth transistor M6 is connected between the second node N2 and the second operation voltage VGL, and has a gate connected to a third node N3. The seventh transistor M7 is connected between the second node N2 and the first node N1, and has a gate connected to the third node N3. The eighth transistor M8 is connected between the second node N2 and the first node N1, and has a gate controlled by the second input signal Gi+4. The second capacitor C2 is connected between the first clock signal CLK and the third node N3. The ninth transistor M9 is connected between the third node N3 and the second operation voltage VGL, and has a gate connected to the first node N1. The tenth transistor M10 is connected between a gate line to which the gate line driving signal Gi is output and the second operation voltage VGL, and has a gate connected to the third node N3. The eleventh transistor M11 is connected between the gate line to which the gate line driving signal Gi is output and the second operation voltage VGL, and has a gate controlled by the second clock signal CLKB.

The operation of the stage STGi having such a configuration is as follows.

When the first input signal Gi−4 is activated to a high level, the first transistor MI is turned on, and the first node N1 is pre-charged to a second voltage DIR level. Since the first clock signal CLK still has a low level, the third transistor M3 is not turned on. At this point, the capacitor C1 operates as a capacitor having a low capacitance. Subsequently, when the first clock signal CLK is shifted to a high level, the third transistor M3 is turned on, and the gate line driving signal Gi having a high level is output. At this point, the second transistor M2 is turned on, and the fourth transistor M4 operates as a capacitor. When the first node N1 has a high level, the ninth transistor M9 is turned on, and the third node N3 has a low level. When the third node N3 has a low level, the sixth, seventh, and tenth transistors M6, M7, and M10 are turned off, and the eleventh transistor M11 is also turned off by the second clock signal CLKB having a low level.

When the first clock signal CLK is shifted to a low level, the third transistor M3 of the pull-up unit 220 is turned off. Also, as the second clock signal CLKB is shifted to a high level, the eleventh transistor M11 of the discharge unit 250 is turned on, and the gate line driving signal Gi for driving a gate line becomes the second operation voltage VGL.

When the second input signal Gi+4 is shifted to a high level, the fifth and eighth transistors M5 and M8 are turned on, and the first and second nodes Ni and N2 are discharged to the third voltage DIRB.

In an embodiment, since the first capacitor C1 is disconnected from the gate line, the influence of a coupling capacitance due to signal lines (for example, a source line or common voltage line) adjacent to the gate line can be minimized, and moreover, coupling with the first clock signal CLK does not arise.

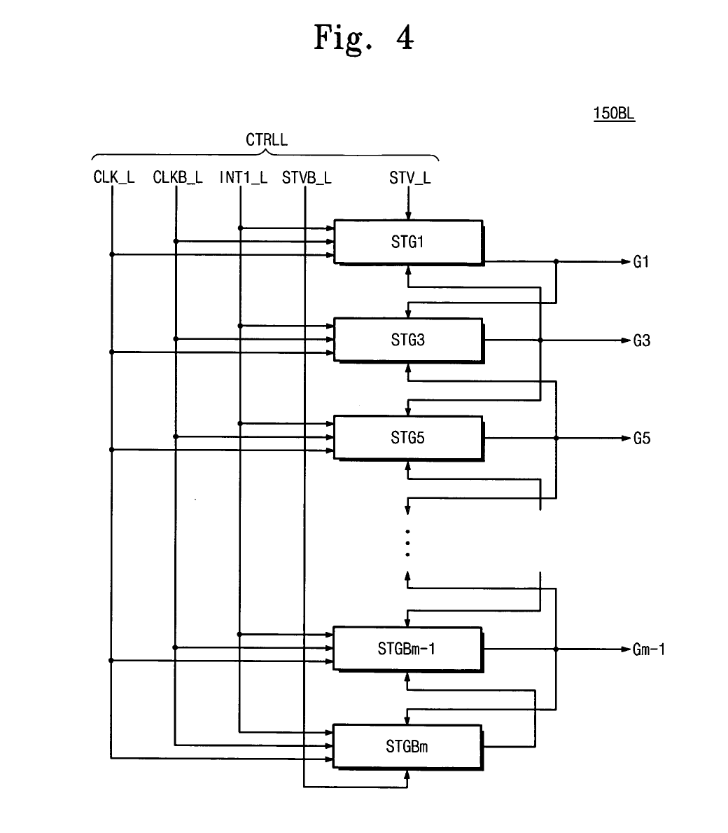

FIG. 4 is a diagram illustrating a detailed configuration of a gate driver according to another embodiment.

Referring to FIG. 4, a gate driver 150BL includes a plurality of stages STGB1 to STGBm−1. The stages STGB1 to STGBm−1 are connected in a cascade structure, and the stages STGB 1 to STGBm−1 other than a final stage STGBm are connected to odd-numbered gate lines in one-to-one correspondence relationship. Each of stages STGB1 to STGBm receives the control signals CTRLL, i.e., first and second clock signals CLK_L and CLKB_L, a control signal INT1_L and vertical start signals STV_L and STVB_L from the timing controller 120 of FIG. 1. Although not shown, each of the stages STGB1 to STGBm receives first to third voltages V1, DIR and DIRB, a first operation voltage VGH, and a second operation voltage VGL from the voltage generator 130.

The stage STGB1 receives the vertical start signal STV_L from the timing controller 120, and the stage STGBm receives the vertical start signal STVB_L from the timing controller 120. Otherwise, the ith (k≠) stage STGBi receives the output of the i−2nd stage STGBi−2, i.e., the gate line driving signal Gi−2 as a first input signal, and receives the output of the i+2th stage STGBi+2, i.e., the gate line driving signal Gi+2 as a second input signal. The stages STGB1 to STGBm−1 output the gate line driving signals GI to Gm−1, respectively.

Similarly to the gate driver 150BL of FIG. 4, a gate driver 150BR for driving the even-numbered gate lines includes a plurality of stages STGB2 to STGBm+1. Similarly to the stages STGBI to STGBm of the gate driver 150BL, the stages STGB2 to STGBm+1 are connected in a cascade structure.

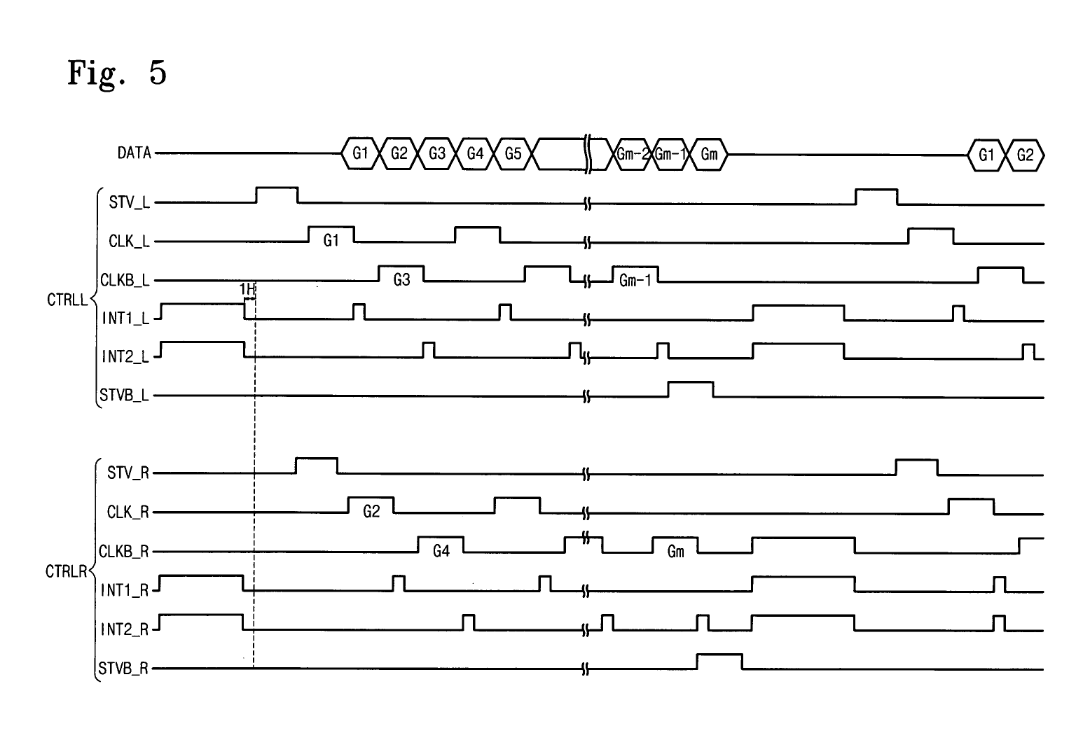

FIG. 5 is a timing diagram of signals used in the gate driver of FIG. 4.

Referring to FIG. 5, the vertical start signals STV_L and STV_R are sequentially activated at the start of one frame. Therefore, the stage STGB I activates the gate line driving signal G1 in response to the first clock signal CLK_L, and the stage STGB2 activates the gate line driving signal G2 in response to the second clock signal CLKB_L. The stage STGBI deactivates the gate line driving signal G1 in response to the first control signal INT1_L, and the stage STGB2 deactivates the gate line driving signal G2 in response to the second control signal INT2_L. In this way, all the gate line driving signals G1 to Gm are sequentially activated, and thus the gate lines are driven.

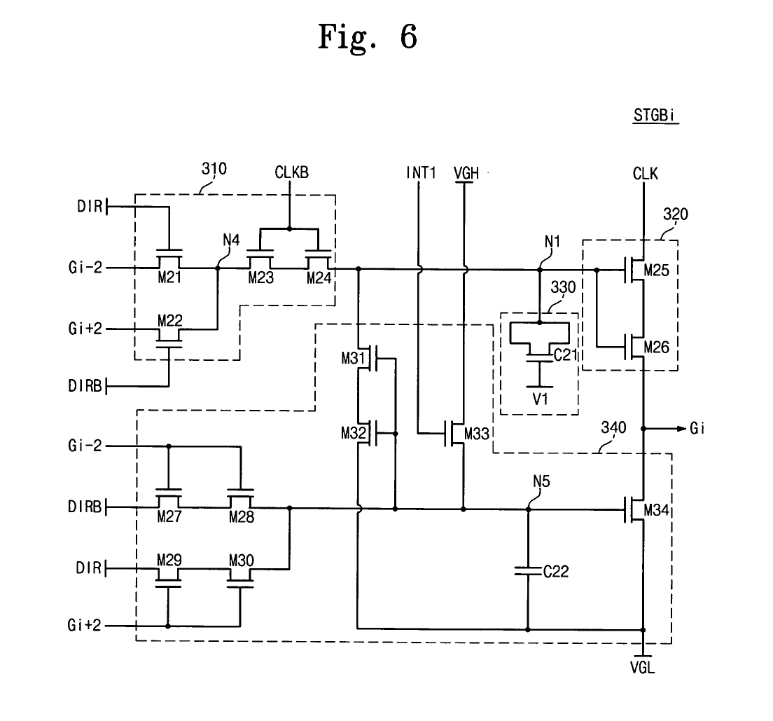

FIG. 6 is a circuit diagram illustrating a detailed configuration of the ith stage in the gate driver of FIG. 4. In the specification, the detailed configuration of the ith stage STGBi is illustrated and described, but the stages STG1 to STGm+1 of the gate drivers 150BL and 150BR have the same configurations as those of the ith stage STGi and operate similarly to the ith stage STGBi. Therefore, clock signals CLK_L and CLK_R are indicated as a first clock signal CLK without discrimination, and clock signals CLKB_L and CLKB_R are indicated as a second clock signal CLKB without discrimination.

Referring to FIG. 6, the stage STGBi includes a pre-charge unit 310, a pull-up unit 320, a boosting unit 330, and a discharge unit 340. The pre-charge unit 310 includes first to fourth transistors M21 to M24. The first transistor M21 is connected between a first input signal Gi−2 and a fourth node N4, and has a gate connected to a second voltage DIR. The second transistor M22 is connected between a second input signal Gi+2 and the fourth node N4, and has a gate connected to a third voltage DIRB. The third and fourth transistors M23 and M24 are sequentially connected in series between the fourth node N4 and a first node N1, and their gates are connected to the second clock signal CLKB.

The pull-up unit 320 includes fifth and sixth transistors M25 and M26. The fifth and sixth transistors M25 and M26 are sequentially connected in series between the first clock signal CLK and a gate line to which the gate line driving signal G1 is output, and their gates are connected to the first node N1.

The boosting unit 330 includes a first capacitor C21. The first capacitor C21 is configured as an active-to-metal capacitor. An active terminal of the first capacitor C21 is connected to the first node N1, and a metal terminal of the first capacitor C21 is connected to a first voltage V1.

For example, if the first capacitor C21 is implemented as an NMOS transistor having an n-type active terminal, the first voltage V1 has a voltage level between a ground voltage and a first operation voltage VGH. If the first capacitor C21 is implemented as a PMOS transistor having a p-type active terminal, the first voltage V1 has a voltage level between the ground voltage and a second operation voltage VGL.

The discharge unit 340 includes seventh to fourteenth transistors M27 to M34, and a second capacitor C22. The seventh and eighth transistors M27 and M28 are sequentially connected in series between a fifth node N5 and the third voltage DIRB, and their gates are connected to the first input signal Gi−2.

The eleventh and twelfth transistors M31 and M32 are sequentially connected in series between the first node N1 and the second operation voltage VGL, and their gates are connected to the fifth node N5. The thirteenth transistor M33 is connected between the first operation voltage VGH and the fifth node N5, and has a gate connected to a first control signal INT1. The second capacitor C22 is connected between a second node N2 and the second operation voltage VGL. The fourteenth transistor M34 is connected between the gate line to which the gate line driving signal Gi is output and the second operation voltage VGL, and has a gate connected to the fifth node N5.

The ith stage STGBi of the stages STGB1 to STGBm in the gate drivers 150BL and 150BR has a configuration of FIG. 6, and the i+1st stage STGBi+1 has the same configuration as that of the ith stage STGBi. In the i+1st stage STGBi+1, however, a first clock signal CLK is input to gates of second and third transistors M22 and M23, and a second clock signal CLKB is input to a drain of a fifth transistor M25. Also, a gate of a thirteenth transistor M33 in the i+1st stage STGBi+1 is connected to the second control signal INT2_L or INT2_R of FIG. 6.

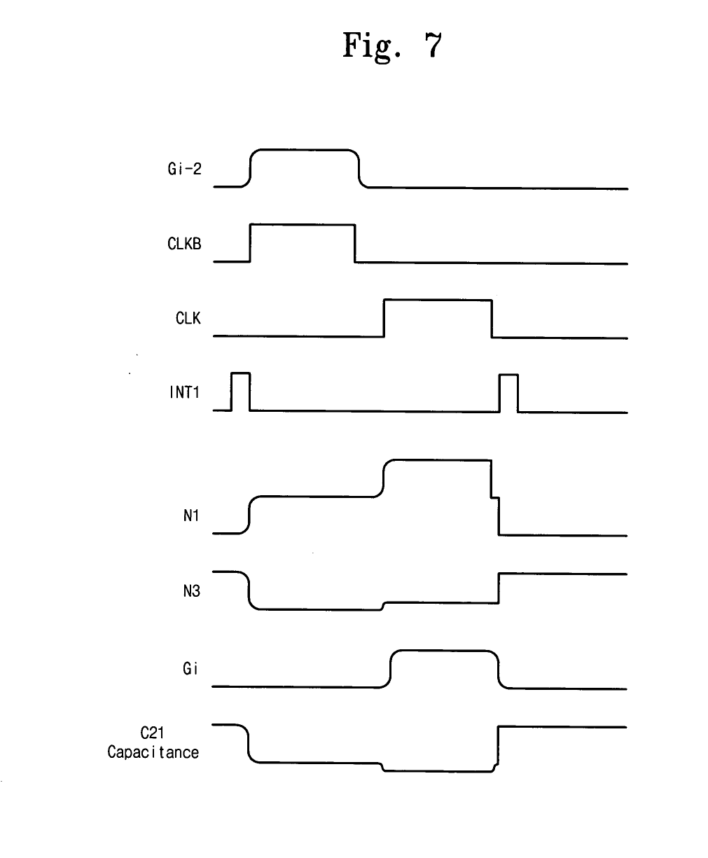

FIG. 7 is a timing diagram of signals used in the ith stage STGBi of FIG. 6.

Referring to FIGS. 6 and 7, when the second clock signal CLKB is shifted to a high level and the first input signal Gi−2 is activated to a high level, the first, third and fourth transistors M21, M23, and M24 are turned on. Therefore, the voltage level of the first node N1 increases. However, since the first clock signal CLK has a low level, the fifth and sixth transistors M25 and M26 are not turned on. At this point, the capacitor C1 operates as a capacitor having a low capacitance.

When the first clock signal CLK is shifted to a high level, the fifth and sixth transistors M25 and M26 are turned on, and the gate line driving signal Gi is shifted to a high level. At this point, the sixth transistor M26 operates as a capacitor, and thus the first node N1 may be boosted.

When the first clock signal CLK is shifted to a low level, the fifth and sixth transistors M25 and M26 are turned off. Then, when the first control signal INT1 is shifted to a high level, the thirteenth transistor M13 is turned on, and the voltage level of the fifth node N5 increases. Therefore, the fourteenth transistor M14 is turned on, and the gate line driving signal Gi is discharged to a second operation voltage VGL level.

As shown in FIG. 5, since the first control signal INT1 is periodically shifted to a high level, the gate line driving signal Gi may be periodically discharged to the second operation voltage VGL. When the voltage level of the fifth node N5 increases by the thirteenth transistor M33, the eleventh and twelfth transistors M31 and M32 are turned on, and the first node N1 is also discharged to the second operation voltage VGL. Moreover, when the second input signal Gi+2 is activated to a high level, the fifth node N5 increases to the second voltage DIR by the ninth and tenth transistors M29 and M30, and thus the first node N1 and the gate line driving signal Gi may be discharged to the second operation voltage VGL. That is, since the fifth node N5 is always driven to a high level in sections other than a section where the gate line driving signal Gi is driven to a high level by the first clock signal CLK, the gate line driving signal Gi may be maintained at the second operation voltage VGL.

In this embodiment, since the first capacitor C11 is disconnected from the gate line, the influence of a coupling capacitance due to signal lines (for example, a source line or common voltage line) adjacent to the gate line can be minimized, and moreover, coupling with the first clock signal CLK does not arise. Moreover, since the first capacitor C11 is implemented as the active-to-metal capacitor, the ripples of the first node N2 and gate line driving signal Gi can be minimized. Furthermore, the change of the voltage level of the fifth node N5 can be minimized by the second capacitor C22, and thus the ripple of the gate line driving signal Gi is reduced.

According to the embodiments, the stable operation of the gate driving circuit is realized and display quality of the display device is enhanced.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A gate driving circuit, comprising:
a pre-charge unit pre-charging a first node in response to a first input signal;
a pull-up unit outputting a gate driving signal for driving a gate line to a first clock signal in response to a signal at the first node;
a first capacitor connected between the first node and a first voltage; and
a discharge unit discharging the first node in response to a second input signal and a second clock signal.

2. The gate driving circuit of claim 1, wherein the first capacitor comprises an active-to-metal capacitor, wherein an active terminal of the active-to-metal capacitor is connected to the first node and a metal terminal of the active-to-metal capacitor is connected to the first voltage.

3. The gate driving circuit of claim 2, wherein:
when the active terminal of the active-to-metal capacitor is an n type active terminal, the first voltage is set to have a voltage level between a ground voltage and a first operation voltage, and
when the active terminal of the active-to-metal capacitor is a p type active terminal, the first voltage is set to have a voltage level between the ground voltage and a second operation voltage.

4. The gate driving circuit of claim 3, wherein the pre-charge unit comprises:
a first transistor connected between a second voltage and a second node, the first transistor having a gate controlled by a first input signal; and
a second transistor connected between the second voltage and the first node, the second transistor having a gate controlled by the first input signal.

5. The gate driving circuit of claim 4, wherein the pull-up unit comprises a third transistor connected between the first clock signal and the gate line, the third transistor having a gate connected to the first node.

6. The gate driving circuit of claim 5, further comprising a fourth transistor connected between the gate line and the second node, the fourth transistor having a gate controlled by a signal of the gate line.

7. The gate driving circuit of claim 6, wherein the discharge unit comprises:
a fifth transistor connected between the second node and a third voltage, the fifth transistor having a gate controlled by a second input signal;
a sixth transistor connected between the second node and the second operation voltage, the sixth transistor having a gate connected to a third node;
a seventh transistor connected between the second node and the first node, the seventh transistor having a gate connected to the third node;
an eighth transistor connected between the second node and the first node, the eighth transistor having a gate controlled by the second input signal;
a second capacitor connected between the first clock signal and the third node;
a ninth transistor connected between the third node and the second operation voltage, the ninth transistor having a gate connected to the first node;
a tenth transistor connected between the gate line and the second operation voltage, the tenth transistor having a gate connected to the third node; and
an eleventh transistor connected between the gate line and the second operation voltage, the eleventh transistor having a gate connected the second clock signal.

8. The gate driving circuit of claim 3, wherein the pre-charge unit comprises:
a first transistor connected between the first input signal and a fourth node, the first transistor having a gate connected to a second voltage;
a second transistor connected between the second input signal and the fourth node, the second transistor having a gate connected to a third voltage; and
third and fourth transistors sequentially connected between the fourth node and the first node in series, the third and fourth transistors respectively having gates connected to the second clock signal.

9. The gate driving circuit of claim 8, wherein the pull-up unit comprises fifth and sixth transistors sequentially connected between the first clock signal and the gate line in series, the fifth and sixth transistors respectively having gates connected to the first node.

10. The gate driving circuit of claim 9, wherein the discharge unit comprises:
seventh and eighth transistors sequentially connected between the third voltage and a fifth node in series, the seventh and eighth transistors respectively having gates connected to the first input signal;
ninth and tenth transistors sequentially connected between the second voltage and the fifth node in series, the ninth and tenth transistors respectively having gates connected to the second input signal;
eleventh and twelfth transistors sequentially connected between the first node and the second operation voltage in series, the eleventh and twelfth transistors respectively having gates connected to the fifth node;
a twelfth transistor connected between the second operation voltage and the fifth node, the twelfth transistor having a gate connected to a control signal;
a second capacitor connected between the fifth node and the second operation voltage; and
a fourteenth transistor connected between the gate line and the second operation voltage, the fourteenth transistor having a gate connected to the fifth node.

11. A display device, comprising:
a display panel comprising a plurality of gate lines, a plurality of source lines perpendicularly intersecting the gate lines, and a plurality of pixels respectively formed at intersection points of the gate lines and source lines;
a first gate driving circuit driving gate lines of a first group of gate lines from among the plurality of gate lines, the first gate driving circuit including a plurality of first stages dependently connected thereto; and
a second gate driving circuit driving gate lines of a second group of gate lines from among the plurality of gate lines, the second gate driving circuit including a plurality of second stages dependently connected thereto,
wherein each stage of the first and second stages includes:
a pre-charge unit pre-charging a first node in response to a first input signal;
a pull-up unit outputting a gate driving signal for driving a gate line to a first clock signal in response to a signal at the first node;
a first capacitor connected between the first node and a first voltage; and
a discharge unit discharging the first node in response to a second input signal and a second clock signal.

12. The display device of claim 11, wherein:
the first group of gate lines is odd-numbered gate lines, and
the second group of gate lines is even-numbered gate lines.

13. The gate driving circuit of claim 12, wherein the first capacitor comprises an active-to-metal capacitor, wherein an active terminal of the active-to-metal capacitor is connected to the first node and a metal terminal of the active-to-metal capacitor is connected to the first voltage.

14. The gate driving circuit of claim 13, wherein:
the first voltage is set to have a voltage level between a ground voltage and a first operation voltage when the active terminal of the active-to-metal capacitor has an n type active terminal, and
the first voltage is set to have a voltage level between the ground voltage and a second operation voltage when the active terminal of the active-to-metal capacitor has a p type active terminal.
